(19) United States
(12) Patent Application Publication
(10) Pub. No.: US 2010/0101639 A1
(43) Pub. Date: Apr. 29, 2010

(54) Optoelectronic device having a multi-layer solder and manufacturing method thereof

(75) Inventor: Jui Hung Yeh, Hsinchu (TW)

Correspondence Address: BACON & THOMAS, PLLC, 625 SLATERS LANE, FOURTH FLOOR, ALEXANDRIA, VA, 22314-1176, US

(73) Assignee: EPISTAR CORPORATION, Hsinchu (TW)

(21) Appl. No.: 12/289,292

(22) Filed: Oct. 24, 2008

(51) Int. Cl. H01L 31/0224; H01L 33/00; H01L 31/18

(52) U.S. Cl. 136/256; 257/99; 438/22; 438/98; 257/E33.063; 257/E31.124

(57) ABSTRACT

An optoelectronic device having a multi-layer solder is disclosed. It included a semiconductor stack, an ohmic layer and a multi-layer solder including a plurality of first type conductive material layers and a plurality of second type conductive material layers. The plurality of first type conductive material layers and the plurality of second type conductive material layers are interlaced each other and the first type conductive material layer is an alloy layer and the second type conductive material layer is a metal layer.

### TECHNICAL FIELD

The application relates to an optoelectronic device having a solder, and more particularly to the multi-layer solder including a plurality of first type conductive material layers and a plurality of second type conductive material layers.

### BACKGROUND

Solders can be used for bonding two components with planar surfaces. The materials of the solder with high melting point have higher mechanical strength, but it is difficult to be processed. On the contrary, the materials of the solder with low melting point have lower mechanical strength, but it is easier for processing. It faces the dilemma for choosing the materials to form the solder.

The material commonly used for soldering in optoelectronic device is alloy for its ease of use during the soldering process. In accordance with FIG. 1, the optoelectronic device includes a semiconductor stack 101, an ohmic layer 102, and a solder 103 wherein the solder is formed of alloy in order to have high mechanical strength, corrosion resistance and heat dissipation.

However, in the manufacturing process of the solder, the content ratio of the alloy is hard to control. The content ratio of the alloy can be adjusted by controlling the thickness of the solder. If the thickness of the solder is changed, the content ratio of the alloy is unacceptable. The melting point of the alloy is also influenced so the yield rate of the die attach is decreased.

### SUMMARY

An optoelectronic device having a multi-layer solder is disclosed. It includes a semiconductor stack, an ohmic layer, and a multi-layer solder including a plurality of first type conductive material layers and a plurality of second type conductive material layers. The plurality of first type conductive material layers and a plurality of second type conductive material layers are interlaced each other while the first type conductive material layer is made of alloy and the second type conductive material layer is made of metal.

A manufacturing method for forming an optoelectronic device comprising the steps of: forming a semiconductor stack; forming an ohmic layer on the semiconductor stack; and forming a multi-layer solder comprising a plurality of first type conductive material layers and a plurality of second type conductive material layers on the ohmic layer wherein the first type conductive material layer and the second conductive material layer are interlaced each other while the first type conductive material layer is made of alloy and the second type conductive material layer is made of metal.

Other features and advantages of the present invention and variations thereof will become apparent from the following description, drawing, and claims.

### BRIEF DESCRIPTION OF THE DRAWINGS

The accompanying drawings incorporated herein provide a further understanding of the invention therefore constitute a part of this specification. The drawings illustrating embodiments of the invention, together with the description, serve to explain the principles of the invention.

FIG. 1 is a cross-section view illustrating the conventional optoelectronic device.

FIG. 2 is a cross-section view illustrating the first embodiment of this invention.

FIG. 3 is a cross-section view illustrating the second embodiment of this invention.

FIG. 4 is an SEM photograph showing the cross-section view of the third embodiment of this invention.

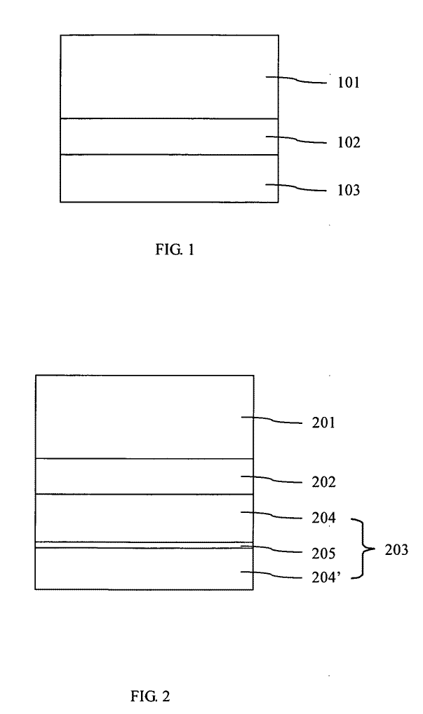

### DETAILED DESCRIPTION OF A PREFERRED EMBODIMENTS

This invention discloses an optoelectronic device. In order to present a more detailed description of present invention, please refer to FIGS. 2-4 and the description hereinafter.

FIG. 2 shows a first embodiment of the present invention. A structure comprising a semiconductor stack 201, an ohmic layer 202, and a multi-layer solder 203 is formed sequentially. The semiconductor stack 201 can be adopted in a light-emitting device or a solar cell.

The semiconductor stack 201 is formed on the ohmic layer 202, wherein the ohmic layer 202is selected from a group consisting of Al, Au, Pt, Zn, Ag, Ni, Ge, In, Sn, Ti, Pb, Cu, or Pd.

Then, the multi-layer solder 203 is formed on the ohmic layer 202 by at least two layers of a first type conductive material layers 204, 204′ and at least one layer of a second type conductive material layer 205 wherein the second conductive material layer 205 is sandwiched by the two layers of the first type conductive material layers 204, 204′. One of the first conductive material layers 204 is disposed on the ohmic layer 202 and another first type conductive material layer 204′ is disposed on the second type conductive material layer 205. One surface of the first type conductive material layer 204′ is exposed.

For the formation of the multi-layer solder, a first bulk formed of alloy is prepared with a predetermined content ratio, and a second bulk of metal is also prepared. Next, a first type conductive material layers 204 is formed by the thermal deposition method from the first bulk to have a predetermined content ratio of the alloy. After the thermal deposition of the first type conductive material layers 204, a second type conductive material layer 205 is formed by thermal deposition method from the second bulk respectively. After the thermal deposition of the second type conductive material layers 205, another first type conductive material layer 204′ is formed by thermal deposition method from the first bulk respectively and the first type conductive material layer 204′ is exposed.

The first type conductive material layers 204, 204′ are formed by alloy with higher melting point, such as AuSn, SnAgCu, SnPb, SnZn, SnAg, SnBi, SnCu, SnSb, SnAgBi, SnAgIn, SnAgCuIn, BiAgGe and SnIn. The second type conductive material layer 205 is formed by a metal layer with lower melting point, such as Sn, Zn, In, Ag, Ge, Sb and Bi. The first type conductive material layers 204, 204′ and the second type conductive material layer 205 are eutectic to each other in the interface. The thickness of each of the first type conductive material layers 204, 204′ is about 2500 Å˜20000 Å; the thickness of the second type conductive material layer 205 is about 50 Å˜1000 Å. In a preferred embodiment, the thickness of the first type conductive material layers 204, 204′ is ten times larger than that of the second type conductive material layer 205.

In this embodiment, the melting point of the multi-layer solder 203 is lower than that of the first type conductive material layer 204, 204′ to facilitate the die attach process, and the mechanical strength of the multi-layer solder 203 is also higher than that of the second type conductive material layer 205. In addition, one surface of the first type conductive material layer 204′ is exposed to protect multi-layer solder structure from oxidation.

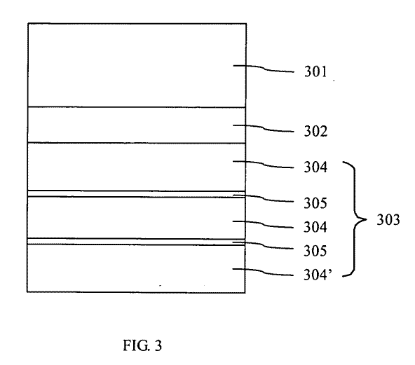

In accordance with FIG. 3, a second embodiment of the present invention is disclosed with a structure comprising a semiconductor stack 301, an ohmic layer 302, and a multi-layer solder 303 sequentially. The semiconductor stack 301 can be adopted in a light-emitting device or a solar cell.

The semiconductor stack 301 is formed on the ohmic layer 302, wherein the ohmic layer 202 is selected from a group consisting of Al, Au, Pt, Zn, Ag, Ni, Ge, In, Sn, Ti, Pb, Cu, or Pd.

Then, the multi-layer solder 303 is formed on the ohmic layer 302 by at least three layers of a first type conductive material layer 304, 304′ and at least two layers of a second type conductive material layer 305 wherein the first type conductive material layers 304, 304′ and the second type conductive material layers 305 are interlaced each other wherein one of the first type conductive material layer 304 is disposed on the ohmic layer 302. In addition, one surface of the first type conductive material layer 304′ is exposed.

For the formation of the multi-layer solder 303, a first bulk formed of alloy is prepared with a predetermined content ratio and a second bulk of metal is also prepared. The first type conductive material layer 304 is formed by the thermal deposition method from the first bulk to having a predetermined content ratio of the alloy. After the thermal deposition of the first type conductive material layer 304, the second type conductive material layer 305 is formed by thermal deposition method from the second bulk, respectively. Followed, another layer of the first type conductive material layer 304 is formed by the thermal deposition method from the first bulk to having a predetermined content ratio of the alloy and another second type conductive material layer 305 is formed by thermal deposition method from the second bulk respectively. The first type conductive material layers 304′ is formed on the second type conductive material layer 305 and one surface of the first type conductive material layer 304′ is exposed.

The first type conductive material layers 304, 304′ are formed by alloy with higher melting point, such as AuSn, SnAgCu, SnPb, SnZn, SnAg, SnBi, SnCu, SnSb, SnAgBi, SnAgIn, SnAgCuIn, BiAgGe and SnIn. The second type conductive material layer 305 is formed by a metal layer with lower melting point, such as Sn, Zn, In, Ag, Ge, Sb and Bi. The first type conductive material layers 304, 304′ and the second type conductive material layer 305 are eutectic to each other in the interface. The thickness of each of the first type conductive material layer 304, 304′ is about 2500 Å˜20000 Å; and the thickness of each of the second type conductive material layer 305 is about 50 Å˜1000 Å. In a preferred embodiment, the thickness of the first type conductive material layer 304, 304′ is ten times larger than that of the second type conductive material layer 305.

In this embodiment, the melting point of the multi-layer solder 303 is lower than that of the first type conductive material layers 304, 304′ to facilitate the die attach process, and the mechanical strength of the multi-layer solder 303 is higher than that of the second type conductive material layer 305. In addition, one surface of the first type conductive material layer 304′ is exposed to protect multi-layer solder structure from oxidation.

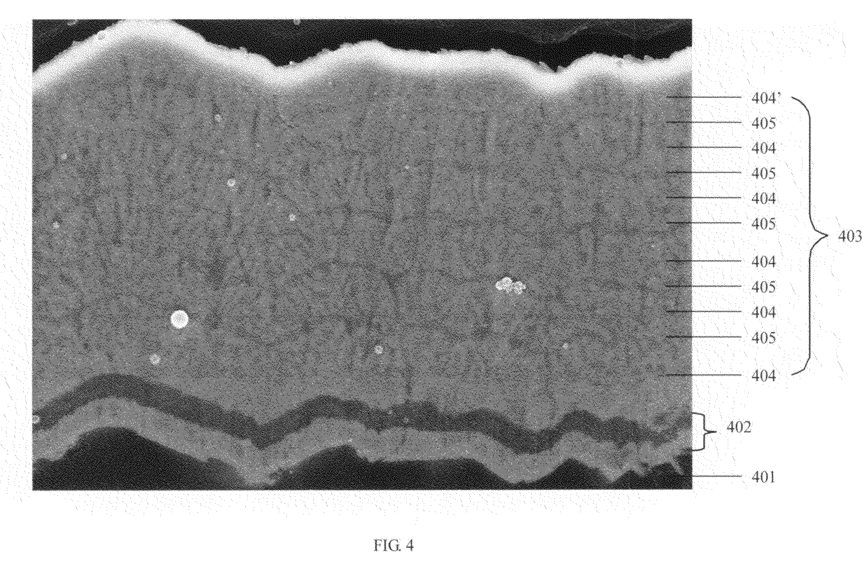

FIG. 4 is an SEM photograph showing the cross-section view of the third embodiment of the present invention. The structure comprises a semiconductor stack 401, an ohmic layer 402, and a multi-layer solder 403 sequentially. The semiconductor stack 401 can be adopted in a light-emitting device or a solar cell.

The semiconductor stack 401 is attached to the multi-layer solder 403 by the ohmic layer 402.

The multi-layer solder 403 is formed by a plurality of the first type conductive material layers 404, 404′ and a plurality of the second type conductive material layer 405 wherein the first type conductive material layers 404, 404′ and the second type conductive material layers 405 are interlaced each other. One of the first type conductive material layers 404 is disposed on the ohmic layer 402, and one surface of the first type conductive material layer 404′ is exposed.

The first type conductive material layers 404, 404′ are formed by alloy with higher melting point, such as AuSn, SnAgCu, SnPb, SnZn, SnAg, SnBi, SnCu, SnSb, SnAgBi, SnAgIn, SnAgCuIn, BiAgGe and SnIn. The second type conductive material layer 405 is formed by a metal layer with lower melting point, such as Sn, Zn, In, Ag, Ge, Sb and Bi. The first type conductive material layer 404, 404′ and the second type conductive material layer 405 are eutectic to each other in the interface. The thickness of each of the first type conductive material layer 404, 404′ is about 2500 Å˜20000 Å; and the thickness of each of the second type conductive material layer 405 is about 50 Å˜1000 Å. In a preferred embodiment, the thickness of the first type conductive material layer 404, 404′ is ten times larger than the second type conductive material layer 405.

The first type conductive material layer 404 and the second type conductive material layer 405 are interlaced each other. The demarcation line of the two layers is formed after the manufacturing process.

The foregoing description has been directed to a specific embodiment of this invention. The multi-layer solder in this invention is a formed by a plurality of the first type conductive material layer and a plurality of the second type conductive material layer wherein the first type conductive material layers and the second type conductive material layers are interlaced each other. The number of the layers is depended on the design but not limited in the description.

It will be apparent; however, that other variations and modifications may be made to the described embodiments, with the attainment of some or all of their advantages. Therefore, it is the object of the appended claims to cover all such variations and modifications that fall within the spirit and scope of the invention.

What is claimed is:

1. An optoelectronic device, comprising:
a semiconductor stack;
an ohmic layer disposed on the semiconductor stack; and
a multi-layer solder disposed on the ohmic layer comprising a least two layers of a first type conductive material layer and a least one layer of a second type conductive material layer wherein the first type conductive material layers and the second type conductive material layer are interlaced each other while the first type conductive material layers are alloy and the second type conductive material layer is metal.

2. The optoelectronic device according to claim 1, wherein the melt point of the first type conductive material layer is higher than the second type conductive material layer.

3. The optoelectronic device according to claim 1, wherein the first type conductive material layer comprises a material selected from AuSn, SnAgCu, SnPb, SnZn, SnAg, SnBi, SnCu, SnSb, SnAgBi, SnAgIn, SnAgCuIn, BiAgGe and SnIn.

4. The optoelectronic device according to claim 1, wherein the second type conductive material layer comprises a material selected from Sn, Zn, In, Ag, Ge, Sb and Bi.

5. The optoelectronic device according to claim 1, wherein the thickness of each of the first type conductive material layer is larger than the thickness of each of the second type conductive material layer.

6. The optoelectronic device according to claim 1, wherein the thickness of each of the first type conductive material layer is about 2500 Å˜20000 Å; and the thickness of each of the second type conductive material layer is about 50 Å˜1000 Å.

7. The optoelectronic device according to claim 1, wherein the first type conductive material layer and the second type conductive material layer are eutectic to each other in the interface.

8. The optoelectronic device according to claim 1, wherein one of the first type conductive material layers is contacted with the ohmic layer.

9. The optoelectronic device according to claim 1, wherein one of the surfaces of the first type conductive material layer is exposed.

10. The optoelectronic device according to claim 1, wherein the semiconductor stack can be adopted in a light-emitting chip or a solar cell.

11. A manufacturing method for forming an optoelectronic device comprising the steps of:
forming a semiconductor stack;
forming an ohmic layer on the semiconductor stack; and
forming a multi-layer solder on the ohmic layer comprising a least two layers of a first type conductive material layer and a least one layer of a second type conductive material layer wherein the first type conductive material layers and the second conductive material layer are interlaced each other while the first type conductive material layers are formed by alloy and the second type conductive material layer is formed by metal.

12. The manufacturing method for forming the optoelectronic device according to claim 11, wherein the first type conductive material layer and the second type conductive material layer are formed separately by thermal deposition method.

13. The manufacturing method for forming the optoelectronic device according to claim 11, wherein the first type conductive material layer comprises a material selected from AuSn, SnAgCu, SnPb, SnZn, SnAg, SnBi, SnCu, SnSb, SnAgBi, SnAgIn, SnAgCuIn, BiAgGe and SnIn.

14. The manufacturing method for forming the optoelectronic device according to claim 11, wherein the second type conductive material layer comprises a material selected from Sn, Zn, In, Ag, Ge, Sb and Bi.

15. The manufacturing method for forming the optoelectronic device according to claim 11, wherein the thickness of each of the first type conductive material layer is larger than the thickness of each of the second type conductive material layer.

16. The manufacturing method for forming the optoelectronic device according to claim 11, wherein the thickness of each of the first type conductive material layer is about 2500 Å˜20000 Å; and the thickness of each of the second type conductive material layer is about 50 Å˜1000 Å.

17. The manufacturing method for forming the optoelectronic device according to claim 11, wherein the first type conductive material layer and the second type conductive material layer are eutectic to each other in the interface.

18. The manufacturing method for forming the optoelectronic device according to claim 11, wherein one of the first type conductive material layers is contacted with the ohmic layer.

19. The manufacturing method for forming the optoelectronic device according to claim 11, wherein one of the surfaces of the first type conductive material layer is exposed.

20. The manufacturing method for forming the optoelectronic device according to claim 11, wherein the semiconductor device can be adopted in a light-emitting chip or a solar cell
